(19) United States
(12) Patent Application Publication
(10) Pub. No.: US 2025/0201678 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventors: Yasutaka NAKASHIBA, Tokyo (JP); Toshiyuki HATA, Tokyo (JP); Hiroshi YANAGIGAWA, Tokyo (JP)

(21) Appl. No.: 18/937,181

(22) Filed: Nov. 5, 2024

(30) Foreign Application Priority Data
Dec. 18, 2023 (JP) 2023-213006

(51) Int. Cl. H01L 23/495; H01L 21/48; H01L 21/56; H01L 23/00; H01L 23/31

(52) U.S. Cl. CPC H01L 23/49562; H01L 21/4842; H01L 21/56; H01L 23/3135; H01L 23/49513; H01L 24/26; H01L 24/32; H01L 24/40; H01L 24/73; H01L 24/83; H01L 24/84; H01L 24/91; H01L 2224/26155; H01L 2224/32058; H01L 2224/32059; H01L 2224/32245; H01L 2224/40245; H01L 2224/73263; H01L 2224/83815; H01L 2224/84815; H01L 2224/92246; H01L 2924/13055; H01L 2924/13091; H01L 2924/3512

(57) ABSTRACT

A semiconductor chip is mounted on a die pad via a solder material. The semiconductor chip includes a plurality of corners including a first corner. A recess portion is formed in the die pad at an upper surface of the die pad. The semiconductor chip is mounted on the die pad such that the first corner is located at an inside of the recess portion. The first corner is located farthest from a center of a sealing body, among the plurality of corners. The solder material has: a first portion that is located between the semiconductor chip and a bottom surface of the recess portion; and a second portion that is located between the semiconductor chip and the upper surface of the die pad. A thickness of the solder material in the first portion is greater than a thickness of the solder material in the second portion.

### CROSS-REFERENCE TO RELATED APPLICATIONS

The disclosure of Japanese Patent Application No. 2023-213006 filed on Dec. 18, 2023 including the specification, drawings and abstract is incorporated herein by reference in its entirety.

### BACKGROUND

The present invention relates to a semiconductor device and a method of manufacturing the same.

There are disclosed techniques listed below.

### PATENT DOCUMENT

[Patent Document 1] Japanese Unexamined Patent Application Publication No. 2004-335776

[Patent Document 2] Japanese Unexamined Patent Application Publication No. 2016-157880

Patent Document 1 discloses a technique of forming a groove on an upper surface of a die pad to improve adhesion with a sealing body. Patent Document 2 discloses, among semiconductor devices in which a semiconductor chip is mounted on a die pad via a solder material, a semiconductor device in which a recess portion is formed in an outer periphery of a back surface of a semiconductor chip.

### SUMMARY

In the semiconductor device in which the semiconductor chip is mounted on the die pad via the solder material, it has been found that a crack may occur in the solder material. The present inventors have examined a technique for preventing or suppressing the occurrence of a crack by contriving the structure of the die pad.

Other objects and novel features will be apparent from the description of the specification and the accompanying drawings.

A semiconductor device according to an embodiment includes a semiconductor chip including a first upper surface and a first lower surface positioned on an opposite side to the first upper surface, a die pad including a second upper surface facing the first lower surface and a second lower surface positioned on an opposite side to the second upper surface, the semiconductor chip being mounted on the die pad, a plurality of leads electrically connected with the semiconductor chip, a metal plate electrically connected with each of the plurality of leads and the semiconductor chip, and a sealing body with which the semiconductor chip and the metal plate are sealed. The semiconductor chip is mounted on the second upper surface of the die pad via a solder material. In plan view, the semiconductor chip includes a plurality of corners including a first corner. A recess portion is formed in the die pad at the second upper surface of the die pad. The semiconductor chip is mounted on the second upper surface of the die pad such that the first corner is located at an inside of the recess portion in transmissive plan view. In transmissive plan view, the first corner is located farthest from a center of the sealing body and is spaced apart from the metal plate, among the plurality of corners. The solder material has: a first portion that is located between the first lower surface of the semiconductor chip and a bottom surface of the recess portion; and a second portion that is located between the first lower surface of the semiconductor chip and the second upper surface of the die pad and that is located at a position which is different from the first portion. A thickness of the solder material in the first portion is greater than a thickness of the solder material in the second portion.

A method of manufacturing a semiconductor device according to another embodiment includes steps of (a) preparing a semiconductor chip including a first upper surface and a first lower surface positioned on an opposite side to the first upper surface, (b) preparing a lead frame having a die pad including a second upper surface and a second lower surface positioned on an opposite side to the second upper surface and a plurality of leads spaced apart from the die pad, (c) mounting the semiconductor chip on the die pad via a solder material such that the first lower surface of the semiconductor chip and the second upper surface of the die pad face to each other, (d) electrically connecting the plurality of leads and the semiconductor chip with each other via a metal plate, and (e) sealing the semiconductor chip and the metal plate. The semiconductor chip prepared in the step of (a) includes a plurality of corners including a first corner. A recess portion is formed in the die pad at the second upper surface of the die pad of the lead frame prepared in the step of (b). In the step of (c), the semiconductor chip is mounted on the second upper surface of the die pad such that the first corner is located at an inside of the recess portion in transmissive plan view; and the solder material is adhered to the entire first lower surface of the semiconductor chip. After the step of (c), the solder material has: a first portion that is located between the first lower surface of the semiconductor chip and a bottom surface of the recess portion; and a second portion that is located between the first lower surface of the semiconductor chip and the second upper surface of the die pad and that is located at a position which is different from the first portion. After the step of (c), a thickness of the solder material in the first portion is greater than a thickness of the solder material in the second portion. After the step of (e), the first corner of the semiconductor chip is located farthest from a center of a sealing body and is spaced apart from the metal plate, among the plurality of corners.

According to the embodiment, it is possible to improve performance of the semiconductor device.

### BRIEF DESCRIPTION OF THE DRAWINGS

FIG. 1 is a top view of a semiconductor device according to an embodiment.

FIG. 2 is a bottom view of the semiconductor device illustrated in FIG. 1.

FIG. 3 is a perspective plan view illustrating an internal structure of the semiconductor device in a state in which a sealing body illustrated in FIG. 2 is removed.

FIG. 4 is a cross-sectional view taken along line A-A of FIG. 3.

FIG. 5 is an explanatory view schematically illustrating an example of a circuit provided in the semiconductor device illustrated in FIG. 1.

FIG. 6 is a main part cross-sectional view illustrating an element structure example of a field-effect transistor illustrated in FIG. 5.

FIG. 7 is an enlarged plan view illustrating a surrounding structure of a corner located farthest from a center of the sealing body in a semiconductor chip illustrated in FIG. 3.

FIG. 8 is an enlarged cross-sectional view taken along line B-B of FIG. 7.

FIG. 9 is an enlarged cross-sectional view illustrating a surrounding structure of a corner located closest to the center of the sealing body in the semiconductor chip illustrated in FIG. 3.

FIG. 10 is a plan view of a recess portion illustrated in FIG. 8 viewed from above a die pad.

FIG. 11 is a perspective plan view illustrating an internal structure of a semiconductor device according to a modification example of FIG. 3.

FIG. 12 is a perspective plan view illustrating an internal structure of a semiconductor device according to another modification example of FIG. 3.

FIG. 13 is a perspective plan view illustrating an internal structure of a semiconductor device according to still another modification example of FIG. 3.

FIG. 14 is an enlarged cross-sectional view illustrating a surrounding structure of each of a plurality of corners of a semiconductor chip illustrated in FIG. 13.

FIG. 15 is a perspective plan view illustrating an internal structure of a semiconductor device according to a modification example of FIG. 13.

FIG. 16 is a plan view of a die pad illustrating a state in which a solder material, a semiconductor chip, and a metal plate illustrated in FIG. 15 are removed.

FIG. 17 is a perspective plan view illustrating an internal structure of a semiconductor device according to another modification example of FIG. 13.

FIG. 18 is an enlarged plan view illustrating a portion of a recess portion having a groove shape illustrated in FIG. 17 on an enlarged scale.

FIG. 19 is an enlarged cross-sectional view taken along line C-C of FIG. 18.

FIG. 20 is a cross-sectional view of a semiconductor device according to a modification example of FIG. 4.

FIG. 21 is an explanatory view illustrating an example of a manufacturing process of the semiconductor device described with reference to FIGS. 1 to 10.

FIG. 22 is an enlarged plan view of a lead frame that is prepared in a lead frame preparation step illustrated in FIG. 21.

FIG. 23 is an enlarged cross-sectional view illustrating an example of a state in which an upper surface of a die pad is irradiated with laser to form a recess portion in the lead frame preparation step illustrated in FIG. 21.

### DETAILED DESCRIPTION

### Description of Description Format, Basic Terms, and Usage in Present Application

In the present application, while an embodiment will be described in a plurality of sections or the like for convenience as necessary, the sections are not independent or distinctive from each other unless otherwise specified, and regardless of the order of descriptions, each section is each portion of a single example, a detailed portion of the other section, a modification example of a part or the whole of the other section, or the like. Also, the description of similar portions will not be repeated in principle. Each component in the embodiment may be optionally provided unless otherwise specified, unless it is theoretically limited to the number of components, and unless it is obvious from the context.

Similarly, in the description of the embodiment and the like, “X made of A” for a material, a composition, or the like does not exclude a material, a composition, or the like containing elements other than A unless otherwise specified and unless it is obvious from the context. For example, regarding a component, it means “X containing A as a main component” or the like. For example, it is needless to say that the term “silicon member” is not limited to pure silicon, and includes a member containing an alloy containing silicon as a main component such as a silicon germanium (SiGe) alloy, an alloy not containing silicon as a main component such as a gallium nitride (GaN) alloy as a main component, other additives, or the like. In addition, gold plating, a Cu layer, nickel plating, or the like includes not only pure members but also a member containing gold, Cu, nickel, or the like as a main component unless otherwise specified.

In addition, when a specific numerical value or quantity is described, the specific numerical value may be a numerical value greater than the specific numerical value or may be a numerical value less than the specific numerical value unless otherwise specified, unless it is theoretically limited to the number, and unless it is obvious from the context.

In each drawing of the embodiment, the same or similar portions are represented by the same or similar symbols or reference numbers, and description will not be repeated in principle.

In the accompanying drawings, hatching or the like may be omitted even in a cross-section when it becomes complicated or when it is clearly distinguished from a blank. Here, when it is obvious from the description and the like, even when a hole is closed in plan, the contour of the background may be omitted. In addition, even when it is not a cross-section, hatching or a dot pattern may be added to specify that it is not a blank or to specify the boundary of a region.

In the following embodiment, as an example of a semiconductor device, a semiconductor device that is called a power device or a power semiconductor device embedded in a power control circuit such as a power supply circuit will be exemplified and described. The semiconductor device described below is embedded in a power conversion circuit, and functions as, for example, a switching element.

### Semiconductor Device

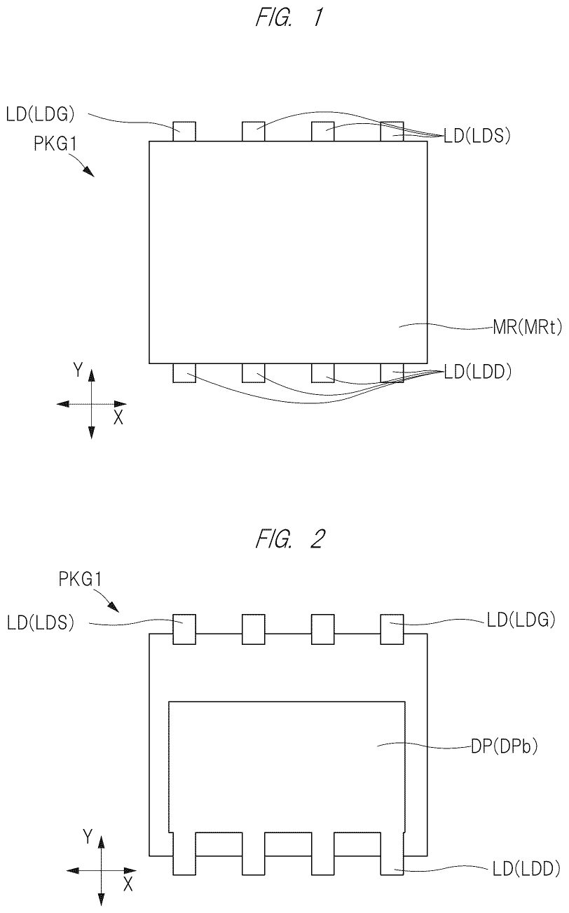

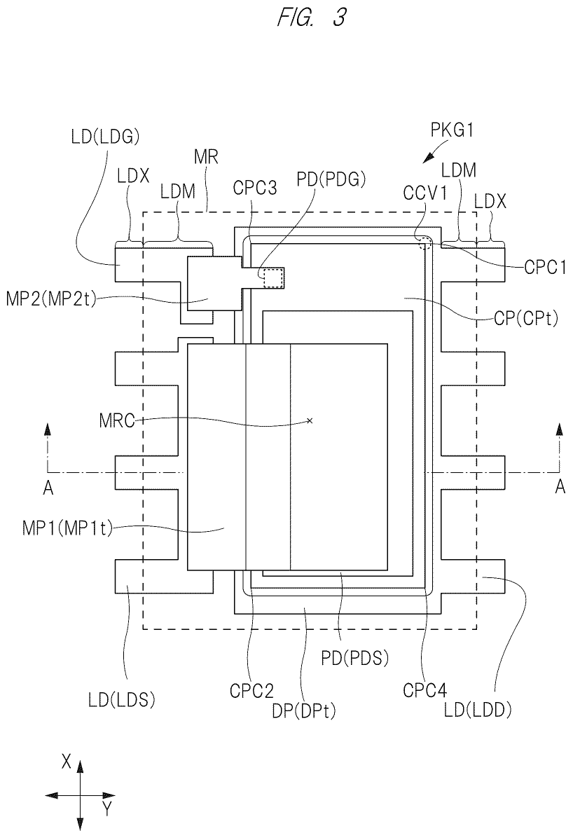

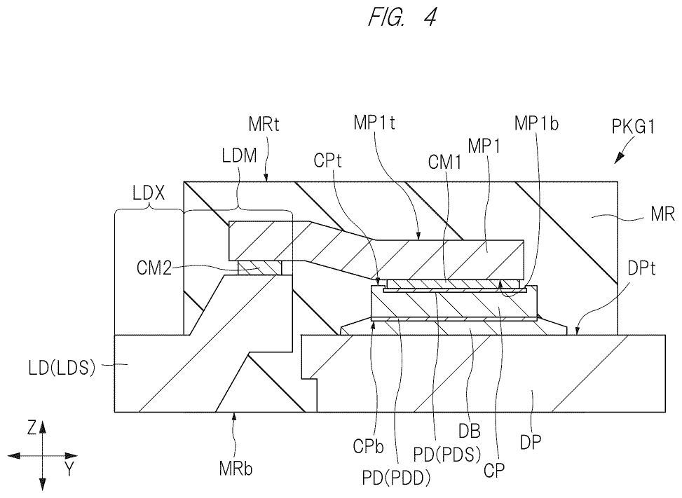

First, a package structure of a semiconductor device PKG1 illustrated in FIG. 1 will be described. FIG. 1 is a top view of a semiconductor device of the present embodiment. FIG. 2 is a bottom view of the semiconductor device illustrated in FIG. 1. FIG. 3 is a perspective plan view illustrating an internal structure of the semiconductor device in a state in which a sealing body illustrated in FIG. 2 is removed. FIG. 4 is a cross-sectional view taken along line A-A of FIG. 3.

In FIGS. 1 to 4, any of an X direction, a Y direction, and a Z direction is described. The Y direction is a direction crossing the X direction, and in the following description, the X direction and the Y direction are perpendicular to each other. The Z direction is a direction perpendicular to each of the X direction and the Y direction. In other words, the Z direction is a normal direction with respect to an X-Y plane including the X direction and the Y direction. In the following description, the term “thickness” means a length in the Z direction in principle. In the following description, the term “plan view” means a plan view as the X-Y plane is viewed.

The semiconductor device PKG1 of the present embodiment includes a semiconductor chip CP (see FIGS. 3 and 4), a die pad on which the semiconductor chip CP is mounted, a plurality of leads LD electrically connected with the semiconductor chip CP, a die pad DP electrically connected with the plurality of leads LD and the semiconductor chip CP, and a sealing body MR with which the semiconductor chip CP is sealed.

As illustrated in FIGS. 1 and 2, the sealing body MR has a quadrangular shape in plan view. In other words, the sealing body MR has four sides in plan view. The sealing body MR includes an upper surface MRt (see FIG. 1) and a lower surface MRb (see FIG. 4) positioned on an opposite side to the upper surface MRt. The sealing body MR is an insulating material made of resin. The sealing body MR may contain a pigment and inorganic insulating particles (silica or the like) in addition to thermosetting resin.

In the present embodiment, the die pad DP illustrated in each of FIGS. 2 to 4 functions as a chip mounting portion on which the semiconductor chip CP is mounted. The die pad DP includes an upper surface (surface or chip mounting surface) DPt, and a lower surface (surface or exposed surface) DPb positioned on an opposite side to the upper surface DPt. The lower surface DPb is exposed from the sealing body MR in the lower surface MRb of the sealing body MR. The die pad DP is made of, for example, a metal material such as copper or a copper alloy.

As illustrated in FIGS. 3 and 4, the semiconductor chip CP is mounted on the upper surface DPt of the die pad DP. As illustrated in FIG. 4, the semiconductor chip CP includes an upper surface (surface, front surface, or main surface) CPt, and a lower surface (surface, back surface, or main surface) CPb positioned on an opposite side to the upper surface CPt. The semiconductor chip CP is mounted on the upper surface DPt of the die pad DP via a solder material DB such that the lower surface CPb faces the upper surface DPt. The solder material DB is a die-bonding material for fixing the semiconductor chip on the die pad DP. In the present embodiment, the solder material DB has a function of electrically connecting the semiconductor chip CP and the die pad DP. As described below as a modification example, the solder material DB may contain solder and a plurality of inorganic particles mixed in solder.

As described below, the semiconductor chip CP of the present embodiment has a power transistor made of a power metal-oxide-semiconductor field-effect (MOSFET) an transistor or insulated gate bipolar transistor (IGBT). Hereinafter, as an example, the semiconductor chip CP having a power MOSFET will be exemplified and described. In the following description, the term “power MOSFET” can be replaced with “IGBT”. Then, the term “drain” is replaced with “collector”, and the term “source” is replaced with “emitter”.

As illustrated in FIGS. 3 and 4, the semiconductor chip CP includes a plurality of pads PD. As illustrated in FIG. 3, the semiconductor chip CP includes a gate electrode pad PDG and a source electrode pad PDS on the upper surface CPt. Specifically, in an insulating film (passivation film) including the upper surface CPt of the semiconductor chip CP, a plurality of opening portions is disposed. Each of the gate electrode pad PDG and the source electrode pad PDS is exposed from the insulating film in the opening portion. An area of the source electrode pad PDS is greater than an area of the gate electrode pad PDG. The gate electrode pad PDG is an electrode pad connected with a gate of the power MOSFET. The source electrode pad PDS is an electrode pad connected with a source of the power MOSFET.

As illustrated in FIG. 4, the semiconductor chip CP includes a drain electrode pad PDD formed on the lower surface CPb. The drain electrode pad PDD is formed on the entire lower surface CPb of the semiconductor chip CP, for example. The drain electrode pad PDD is an electrode pad connected with a drain of the power MOSFET.

In the present embodiment, the die pad DP is electrically connected with the semiconductor chip CP. Specifically, the die pad DP is electrically connected with the drain electrode pad PDD of the semiconductor chip CP via the solder material DB, which is a conductive member. The die pad DP is formed integrally with a lead LDD, that is a lead for drain, among the plurality of leads LD illustrated in FIG. 3. The die pad DP configures a flow path of a drain current.

As illustrated in FIGS. 3 and 4, each of the plurality of leads LD includes an inner lead portion LDM sealed with the sealing body MR and an outer lead portion LDX exposed from the sealing body MR. As illustrated in FIG. 1, in plan view, the plurality of leads LD is arranged on only two sides positioned on opposite sides to each other, among the four sides of the sealing body MR. The outer lead portion LDX (see FIG. 3) of each of the plurality of leads LD protrudes outward from a side surface of the sealing body MR.

As illustrated in FIG. 3, among the plurality of leads LD, a plurality of leads LDS for source is electrically connected with the source electrode pad PDS via a metal plate (clip) MP1. A plate-shaped member for connecting the semiconductor chip and the lead is called a clip. In the present embodiment, as illustrated in FIG. 3, a configuration in which the plurality of leads LDS for source is connected with each other is described as an example, but the plurality of leads LDS for source may not be connected with each other. Among the plurality of leads LD, a lead LDG for gate is electrically connected with the gate electrode pad PDG via a metal plate (clip) MP2. Among the plurality of leads LD, a lead LDD, that is a lead for drain, is formed integrally with the die pad DP, and is electrically connected with the drain electrode pad PDD via the die pad DP.

As in the present embodiment, when the leads LDS for source and the source electrode pad PDS are electrically connected via the metal plate MP1, it is possible to increase a path cross-sectional area of a source current. Therefore, it is possible to reduce resistance of a supply path of a current (source current) flowing in the source electrode pad PDS.

As illustrated in FIG. 4, the metal plate MP1 includes an upper surface (surface) MP1t and a lower surface (surface) MP1b that is positioned on an opposite side to the upper surface MP1t and faces the semiconductor chip CP. In the example illustrated in FIG. 4, the entire metal plate MP1 including the upper surface MP1t is sealed with the sealing body MR. The metal plate MP1 is made of, for example, a metal material containing copper, a copper alloy, or iron such as 42 alloy.

As a modification example, the upper surface MP1t may be exposed from the sealing body MR in the upper surface MRt of the sealing body MR. Here, for example, it is possible to improve heat radiation property of the semiconductor device by connecting a heat radiation member (not illustrated) with the upper surface MP1t. Alternatively, by connecting a terminal for source current (not illustrated) with the upper surface MP1t, it is possible to use the terminal as a supply path of a source current.

The metal plate MP1 is electrically connected with the source electrode pad PDS via a conductive member CM1. The conductive member CM1 is bonded to the lower surface MP1b of the metal plate MP1 and an upper surface of the source electrode pad PDS. The metal plate MP1 is electrically connected with the lead LDS via a conductive member CM2. The conductive member CM2 is bonded to the lower surface MP1b of the metal plate MP1 and an upper surface of the lead LDS. Each of the conductive member CM1 and the conductive member CM2 is made of, for example, solder or conductive resin. The conductive resin is resin in which a plurality of conductive particles is mixed in a resin component containing thermosetting resin such as epoxy resin.

While a cross-sectional structure of the metal plate MP2 electrically connecting the lead LDG for gate and the gate electrode pad PDG illustrated in FIG. 3 is not illustrated, similarly to the metal plate MP1 illustrated in FIG. 4, the metal plate MP2 is electrically connected with each of the lead LDG and the gate electrode pad PDG via a conductive member (a member similar to the conductive member CM1 or the conductive member CM2 of FIG. 4).

Though not illustrated, as a modification example of the present embodiment, a wire may be used instead of the metal plate MP2 illustrated in FIG. 3 as a conductive member for electrically connecting the lead LDG for gate and the gate electrode pad PDG. A gate current flowing in the gate electrode pad PDG is a signal current that controls a switching operation of a transistor. Therefore, a path cross-sectional area of the gate current may be smaller than the path cross-sectional area of the source current.

Note that, as in the present embodiment, when the lead LDG for gate and the gate electrode pad PDG are electrically connected via the metal plate MP2, a waveform quality of a gate signal is improved compared to when the lead LDG and the gate electrode pad PDG are electrically connected via a wire (not illustrated). That is, from a viewpoint of improving the waveform quality of the gate signal, it is preferable that the lead LDG and the gate electrode pad PDG are electrically connected via the metal plate MP2 as in the present embodiment.

Alternatively, when the lead LDG for gate and the gate electrode pad PDG are electrically connected via the metal plate MP2, it is possible to fix the metal plate MP1 and the metal plate MP2 together at the same timing. Accordingly, as in the present embodiment, when the lead LDS for source and the source electrode pad PDS are electrically connected via the metal plate MP1, it is preferable that the lead LDG and the gate electrode pad PDG are electrically connected via the metal plate MP2 in that it is possible to improve the manufacturing efficiency of the semiconductor device.

### Circuit Configuration Example

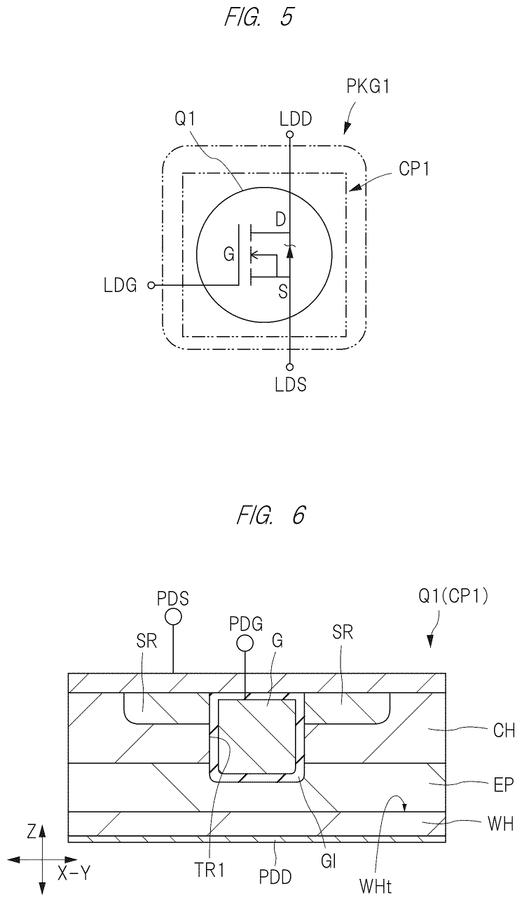

Next, an example of a configuration of a circuit provided in the semiconductor device PKG1 illustrated in FIG. 3 and an example of an element structure of a transistor will be described. FIG. 5 is an explanatory view schematically illustrating an example of a circuit provided in the semiconductor device illustrated in FIG. 1. FIG. 6 is a main part cross-sectional view illustrating an element structure example of a field-effect transistor illustrated in FIG. 5.

In semiconductor devices for power control, called power semiconductor devices, a semiconductor device having a semiconductor element such as a diode, a thyristor, or a transistor is known. While the transistor is used in various fields, as in the present embodiment, for example, a transistor that is embedded in a power control circuit in which a large current of 1 A (ampere) or more flows and that operates as a switching element is called a power transistor. As illustrated in FIG. 5, the semiconductor device PKG1 of the present embodiment includes the semiconductor chip CP including a transistor Q1, that is a power transistor. In the example illustrated in FIGS. 5 and 6, the transistor Q1 provided in the semiconductor chip CP is a field-effect transistor, specifically, a MOSFET. In the power semiconductor device, the transistor is used as, for example, a switching element. The MOSFET that is used in the power semiconductor device is called a power MOSFET.

The above-described MOSFET is described as a general term for a field-effect transistor having a structure in which a gate electrode made of a conductive material is disposed on a gate insulating film. Accordingly, even when described using the term MOSFET, a gate insulating film other than an oxide film is not excluded. Also, even when described using the term MOSFET, for example, a gate electrode material such as polysilicon other than metal is not excluded.

The transistor Q1 illustrated in FIG. 5 is formed of, for example, an n-channel field-effect transistor as illustrated in FIG. 6. FIG. 6 is a main part cross-sectional view illustrating structure example of a field-effect transistor an element illustrated in FIG. 5.

In the example illustrated in FIG. 6, an n type epitaxial layer EP is formed on a main surface WHt of a semiconductor substrate WH made of, for example, n− type monocrystalline silicon. The semiconductor substrate WH and the epitaxial layer EP compose a drain region (a region corresponding to a drain D illustrated in FIG. 5) of the MOSFET. The drain region is electrically connected with the drain electrode pad PDD formed on the back surface of the semiconductor chip CP.

A channel forming region CH, that is a p+ type semiconductor region, is formed on the epitaxial layer EP, and a source region (a region corresponding to a source S illustrated in FIG. 5) SR, that is an n+ type semiconductor region, is formed on the channel forming region CH. The source region SR is electrically connected with the source electrode pad PDS of the semiconductor chip CP via a lead wire. In the semiconductor region stacked on the semiconductor substrate WH, a trench (opening portion, groove) TRI that passes through the channel forming region CH from an upper surface of the source region SR and reaches the inside of the epitaxial layer EP is formed.

A gate insulating film GI is disposed on an inner wall of the trench TR1. A gate G stacked to fill the trench TR1 is disposed on the gate insulating film GI. The gate G is electrically connected with the gate electrode pad PDG of the semiconductor chip CP via a lead wire.

In the transistor Q1, since the drain region and the source region SR are disposed in a thickness direction with the channel forming region CH interposed therebetween, a channel is formed in the thickness direction (hereinafter, referred to as a vertical channel structure). Here, it is possible to reduce an area occupied by elements in plan view compared to a field-effect transistor in which a channel is formed along the main surface WHt. Therefore, it is possible to reduce a planar size of the semiconductor chip CP.

In the above-described vertical channel structure, since it is possible to increase a channel width per unit area in plan view, it is possible to reduce on-resistance. FIG. 6 is a diagram illustrating the element structure of the field-effect transistor, and in the semiconductor chip CP illustrated in FIG. 5, a plurality (a large number) of transistors Q1 having the element structure as illustrated in FIG. 6 is connected in parallel. Accordingly, for example, it is possible to configure a power MOSFET in which a large current exceeding, for example, 1 ampere flows.

As described above, when the plurality of transistors Q1 having the vertical channel structure is connected in parallel to configure the MOSFET, the electric characteristics (mainly, breakdown voltage characteristic, on-resistance characteristic, capacitance characteristic) of the MOSFET change depending on the planar size of the semiconductor chip CP. For example, if the planar area of the semiconductor chip CP increases, the number of cells (that is, the number of elements) of the transistors Q1 connected in parallel increases, so that on-resistance decreases and capacitance increases.

In FIGS. 5 and 6, while the MOSFET is illustrated as an example of a power transistor provided in the power semiconductor device, various modification examples can be applied. For example, an insulated gate bipolar transistor (IGBT) may be provided instead of the MOSFET.

In the example illustrated in FIG. 6, while the transistor having the vertical channel structure has been described by way of an example, the transistor having the vertical channel structure can also be replaced with a transistor having a horizontal channel structure. Here, the drain electrode pad PDD is disposed on the upper surface CPt (see FIG. 3) of the semiconductor chip CP. Therefore, the lead LDD for drain illustrated in FIG. 3 and the drain electrode pad PDD (see FIG. 6) connected with a drain of the transistor having the horizontal channel structure are electrically connected via a wire (wire for drain) (not illustrated).

### Crack in Solder Material

Next, a cause of a crack in the solder material DB illustrated in FIGS. 3 and 4 and a measure to prevent the occurrence of the crack will be described. In the following description, a semiconductor device that is described as an examination example of the present embodiment is similar to the semiconductor device PKG1 illustrated in FIGS. 3 and 4, except that the entire the upper surface DPt of the die pad DP is a flat surface. Therefore, the semiconductor device of the examination example will not be illustrated in the drawings, and description will be provided using the numerals of the parts of the semiconductor device PKG1 illustrated in FIGS. 1 to 4 as necessary.

The present inventors have examined the semiconductor device of the examination example and have found that a crack may occur in a part of the solder material DB illustrated in FIG. 3 due to a temperature cycle load or the like applied after the semiconductor device is completed. It has been found that, after a crack occurs in a part of the solder material DB, if the temperature cycle load is further applied, the range of the crack spreads starting from a place where the crack occurred initially.

As described above, since the solder material DB has a function as a conductive member electrically connecting the semiconductor chip CP and the die pad DP, if a crack grows over a wide range of the solder material DB, electric characteristics of the semiconductor device are deteriorated.

Alternatively, since the solder material DB has a function as a fixing member fixing the semiconductor chip CP on the die pad DP, if a crack grows over a wide range of the solder material DB, performance of the semiconductor device may be deteriorated due to deterioration of fixing strength of the semiconductor chip CP.

Accordingly, the present inventors examined a technique for suppressing occurrence of a crack. As a result of the examination, it has been found that there are several structural features at places where a crack occurs initially.

First, as the semiconductor chip CP illustrated in FIG. 3, when the semiconductor chip has a polygonal shape having a plurality of corners in plan view, it has been found that a crack occurs near any of the plurality of corners. For example, in the example illustrated in FIG. 3, the semiconductor chip CP has a quadrangular shape including a corner CPC1, a corner CPC2, a corner CPC3, and a corner CPC4 in plan view.

It is considered that a crack that occurs due to a temperature cycle load occurs as follows. That is, temperature increase and temperature decrease are repeated, so that stress is repeatedly applied to the vicinity of a bonding interface of members having different linear expansion coefficients (a bonding interface of the semiconductor chip CP and the solder material DB illustrated in FIG. 4). A crack of the solder material DB occurs when an external force exceeding a limit in terms of the strength of the solder material DB is applied near a place where the stress is concentrated.

When the semiconductor chip has a polygonal shape including a plurality of corners, stress concentration is likely to occur near each corner. Therefore, when the semiconductor chip has a polygonal shape including a plurality of corners, it is considered that a crack is likely to occur at each corner.

Second, it has been found that a crack is particularly likely to occur near a specific corner, among the plurality of corners of the semiconductor chip. Specifically, it has been found that a crack is particularly likely to occur near a corner at a position farthest from a center of the sealing body, among the plurality of corners of the semiconductor chip. For example, in the example illustrated in FIG. 3, the corner CPC1 is a corner farthest from a center MRC of the sealing body MR, among the four corners of the semiconductor chip CP (corner CPC1, corner CPC2, corner CPC3, and corner CPC4) in transmissive plan view. Accordingly, when a crack occurs in the solder material DB, a crack is particularly likely to occur near the corner CPC1.

According to the examination of the present inventors, it has been found that a crack is less likely to occur even in the corner located farthest from the center MRC of the sealing body MR when the corner is covered with the metal plate MP1 via the conductive member CM1 (see FIG. 4) or is located near the metal plate MP1. For example, in the example illustrated in FIG. 3, the corner CPC1 is a corner at a position spaced apart from the metal plate MP1. The phrase “the corner CPC1 is a corner at a position spaced apart from the metal plate MP1” can be reworded as “the corner CPC1 does not overlap the metal plate MP1 in transmissive plan view”. When the corner CPC1 is covered with the metal plate MP1 via the conductive member CM1 (see FIG. 4) in transmissive plan view, a crack will be less likely to occur near the corner CPC1, but in the example illustrated in FIG. 3, a crack is likely to occur.

In the example illustrated in FIG. 3, strictly, a distance between the center MRC of the sealing body MR and the corner CPC1 in transmissive plan view is longer than a distance between the center MRC of the sealing body MR and the corner CPC4. Note that the difference is within three percent of the distance between the center MRC of the sealing body MR and the corner CPC1, and the distance between the center MRC of the sealing body MR and the corner CPC1 in transmissive plan view and the distance between the center MRC of the sealing body MR and the corner CPC4 can be regarded to be substantially equal to each other.

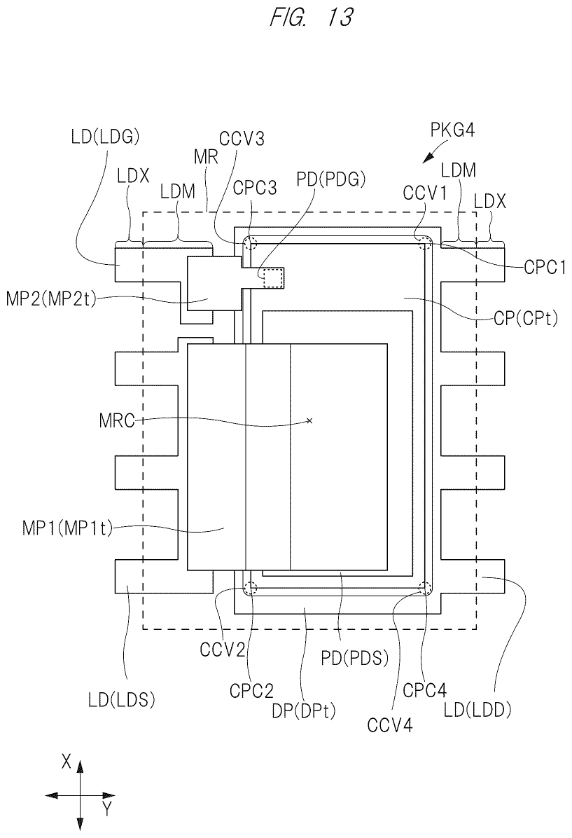

Here, as a semiconductor device PKG4 illustrated in FIG. 13 described below as a modification example, it is preferable that a recess portion CCV1 is formed at a position, that overlaps the corner CPC1, and a recess portion CCV4 is formed at a position, that overlaps the corner CPC4.

However, in the semiconductor device PKG1 illustrated in FIG. 3, a recess portion is not provided at a position, that overlaps the corner CPC4 and is provided only at a position, that overlaps the corner CPC1 for the following reason.

That is, when there is a plurality of corners where “the distance from the center MRC of the sealing body MR” as a first factor is the same (or can be regarded to be substantially the same), a crack is likely to occur near a corner at a position where “the distance from the metal plate MP1” as a second factor is far. In the example illustrated in FIG. 3, the corner CPC1 is located farthest from the metal plate MP1, among the plurality of corners of the semiconductor chip CP in transmissive plan view. In comparison of the corner CPC1 and the corner CPC4, the corner CPC1 is at a position further spaced apart from the metal plate MP1 with respect to the corner CPC4 in transmissive plan view. The difference is not merely few percent, and a shortest distance between the corner CPC1 and the metal plate MP1 is two times or more a shortest distance between the corner CPC4 and the metal plate MP1. Here, the corner CPC1 cannot be regarded to be located near the metal plate MP1. Then, a crack occurs in the vicinity of the corner CPC1 at a higher frequency than in the vicinity of the corner CPC4. Therefore, in comparison of the corner CPC1 and the corner CPC4, the recess portion CCV1 as a measure to suppress a crack is provided in the corner CPC1 with priority.

Though not illustrated as the drawings, as a modification example of FIG. 3, the corner CPC1 may be covered with the metal plate MP1 via the conductive member CM1 (see FIG. 4). Here, a crack is likely to occur near the corner CPC4 that is located second farthest from the center MRC of the sealing body MR next to the corner CPC1 and is at a position spaced apart from the metal plate MP1. Considering that some of the plurality of corners are covered with the metal plate MP1, the following can be said. That is, in the example illustrated in FIG. 3, the corner CPC1 is a corner located farthest from the center MRC of the sealing body MR, among the plurality of corners of the semiconductor chip CP at positions spaced apart from the metal plate MP1 in transmissive plan view.

As described above, from the examination of the present inventors, since a place in the solder material DB where a crack is likely to occur can be specified, it is possible to reduce a risk of occurrence of a crack by taking a measure at least at a place where a crack is likely to occur.

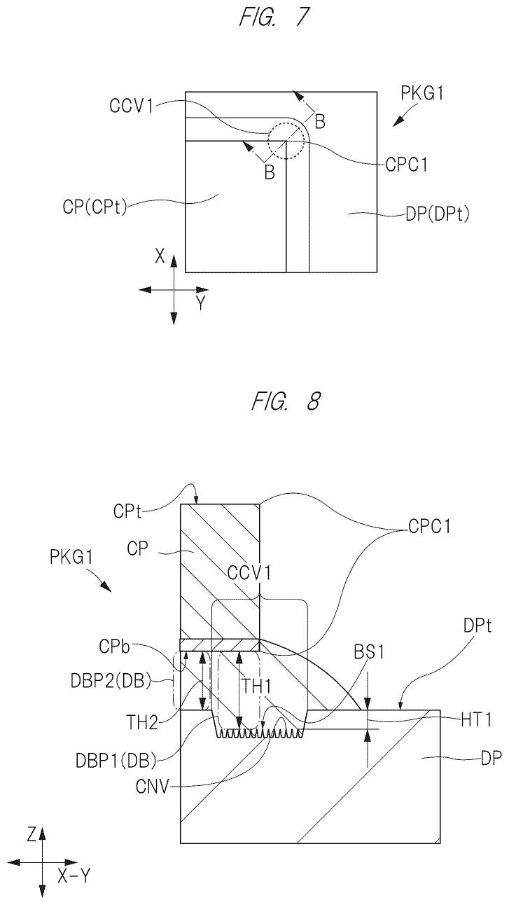

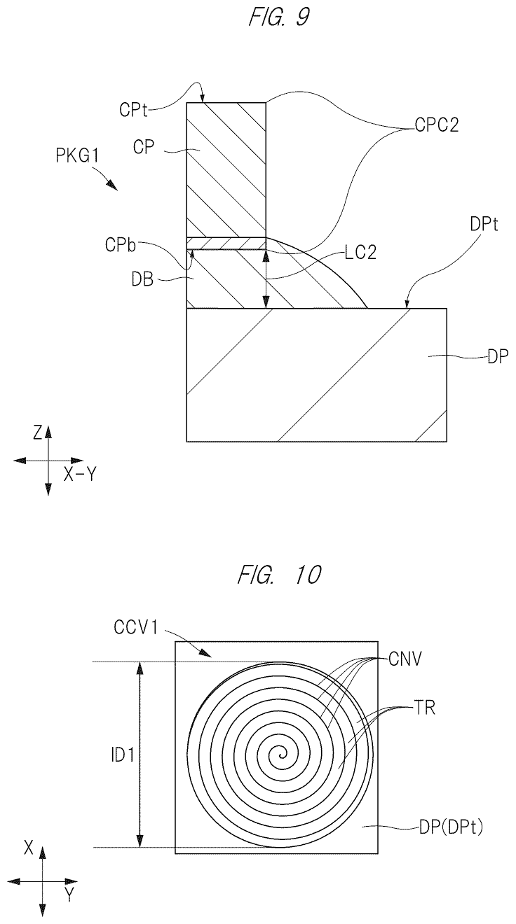

Next, a measure to suppress the occurrence of a crack will be described. FIG. 7 is an enlarged plan view illustrating a surrounding structure of a corner located farthest from the center of the sealing body in the semiconductor chip illustrated in FIG. 3. FIG. 8 is an enlarged cross-sectional view taken along line B-B of FIG. 7. FIG. 9 is an enlarged cross-sectional view illustrating a surrounding structure of a corner located closest to the center of the sealing body in the semiconductor chip illustrated in FIG. 3. FIG. 10 is a plan view of a recess portion illustrated in FIG. 8 viewed from above the die pad. FIG. 9 illustrates a cut cross-section passing through the corner CPC2 of FIG. 3.

As illustrated in FIGS. 7 and 8, the recess portion CCV1 is formed in the die pad DP at the upper surface DPt of the die pad DP. As illustrated in FIG. 7, the semiconductor chip CP is mounted on the upper surface DPt of the die pad DP such that the corner CPC1 is located at an inside of the recess portion CCV1 in transmissive plan view (that is, the corner CPC1 is located at the inside of the recess portion CCV1).

As illustrated in FIG. 8, the solder material DB has a portion DBP1 that is located between the lower surface CPb of the semiconductor chip CP and a bottom surface BS1 of the recess portion CCV1, and a portion DBP2 that is located between the lower surface CPb of the semiconductor chip CP and the upper surface DPt of the die pad DP, the portion DBP2 being at a position different from the portion DBP1. A thickness TH1 of the solder material DB in the portion DBP1 is greater than a thickness TH2 of the solder material DB in the portion DBP2.

In other words, in the present embodiment, the recess portion CCV1 is formed in the die pad DP at a position, that overlaps the corner CPC1 of the semiconductor chip CP, of the upper surface DPt of the die pad DP, and the recess portion CCV1 is filled with the solder material DB. Accordingly, the thickness of the solder material DB is set such that the thickness TH1 at a position, that overlaps the corner CPC1 of the semiconductor chip CP is locally greater than the thickness TH2 in other portions (for example, the portion DBP2).

When a thick portion in which the thickness of the solder material DB is locally thick (for example, the portion DBP1 of FIG. 8) is provided, stress relaxation performance in the thick portion is improved. In the present embodiment, a portion where a crack is likely to occur due to the stress concentration caused by the temperature cycle load is the portion DBP1, that is the thick portion. As a result, it is possible to suppress the occurrence of a crack in the portion DBP1. When stress concentration occurs in the portion DBP1, stress in the vicinity of the portion DBP1 is relaxed. Therefore, it is possible to suppress the occurrence of a crack even in a portion in the vicinity of the portion DBP1 by taking a measure to suppress the occurrence of a crack in the portion DBP1 where stress concentration is likely to occur.

In the present embodiment, the thickness of a place where a crack is most likely to occur, that is, the portion DBP1 overlapping the corner CPC1 of the semiconductor chip CP is selectively thick. A recess portion is not formed in a portion other than the recess portion CCV1 in the die pad DP at the upper surface DPt of the die pad DP. For example, the recess portion CCV1 is not formed at a position, that overlaps the corner CPC2 located closest to the center MRC of the sealing body MR, among the plurality of corners of the semiconductor chip CP illustrated in FIG. 3. In other words, the corner CPC2 is located at an outside of the recess portion CCV1 in transmissive plan view. Therefore, as illustrated in FIG. 9, a shortest distance LC2 from the lower surface CPb of the semiconductor chip CP at the corner CPC2 to the upper surface DPt of the die pad DP is smaller than the thickness TH1 of the solder material DB in the portion DBP1 illustrated in FIG. 8. The shortest distance LC2 from the lower surface CPb of the semiconductor chip CP at the corner CPC2 to the upper surface DPt of the die pad DP is equal to the thickness TH2 of the solder material DB in the portion DBP2 illustrated in FIG. 8.

In the example illustrated in FIG. 3, the recess portion CCV1 is not formed at each of a position overlapping the corner CPC3 of the semiconductor chip CP and a position overlapping the corner CPC4 in the upper surface of the die pad DP. Though not illustrated in the drawings, the thickness of the solder material DB at each of the position overlapping the corner CPC3 and the position overlapping the corner CPC4 of the semiconductor chip CP illustrated in FIG. 3 is equal to the thickness TH2 illustrated in FIG. 8.

As described below, as a modification example of the present embodiment, a recess portion may be formed at the position overlapping each of the plurality of corners of the semiconductor chip CP. In comparison with the semiconductor device according to the modification example, in the semiconductor device PKG1 illustrated in FIG. 3, the corner CPC1 among the plurality of corners may be aligned to be located at an inside of the recess portion CCV1 in a die-bonding step. Therefore, it is preferable in that alignment is simply performed compared to the modification example where alignment is performed for a plurality of corners and a plurality of recess portions.

In the present embodiment, the recess portion CCV1 illustrated in FIGS. 7, 8, and 10 is formed by irradiating in the die pad DP at the upper surface DPt of the die pad DP with laser. As a modification example of the present embodiment, a method for forming the recess portion CCV1 by press working using a mold for molding can be provided as an example. In a case of a method of forming the recess portion CCV1 by laser irradiation, it is preferable in that unevenness or distortion is less likely to occur in the upper surface DPt in the vicinity of the recess portion CCV1 compared to the method of forming the recess portion CCV1 by press working.

In the present embodiment, the recess portion CCV1 is formed by scanning with laser having a spot diameter smaller than an opening diameter (or an opening width) of the recess portion CCV1. Here, it is preferable in that it is possible to control the opening area or depth of the recess portion CCV1 with high accuracy.

As described above, when the recess portion CCV1 is formed by scanning with laser having a spot diameter smaller than the opening diameter or opening width of the recess portion CCV1, the recess portion CCV1 having a shape as illustrated in FIGS. 8 and 10 is obtained. That is, as illustrated in FIG. 8, a groove-shaped unevenness is formed in the recess portion CCV1 at the bottom surface BS1 of the recess portion CCV1.

In the example illustrated in FIG. 10, in plan view, an outer edge of the recess portion CCV1 has a circular shape, and the groove-shaped unevenness has a spiral shape. An opening diameter ID1 of the recess portion CCV1 is, for example, about 400 μm. The shape illustrated in FIG. 10 is obtained when irradiation is continuously performed to draw a circle from the center toward the outer edge of the recess portion CCV1 or when irradiation is continuously performed to draw a circle from the outer edge toward the center of the recess portion CCV1. Here, a plurality of protrusion portions CNV is continuously connected. A plurality of groove portions TR is continuously connected.

As illustrated in FIG. 8, the thickness TH1 of the solder material DB in the portion DBP1 is defined as a shortest distance from a tip of the protrusion portion CNV in the bottom surface BS1 to the lower surface CPb of the semiconductor chip CP. From a viewpoint of exerting a stress relaxation function in the portion DBP1, it is preferable that a height difference HT1 between the protrusion portion CNV of the bottom surface BS1 of the recess portion CCV1 and the upper surface DPt of the die pad DP is 30 μm or more.

### Modification Examples of Layout of Semiconductor Chip

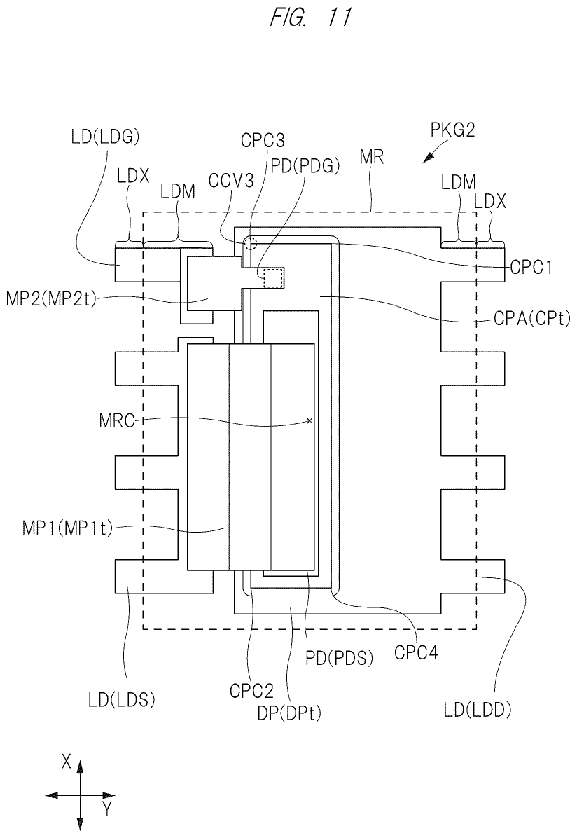

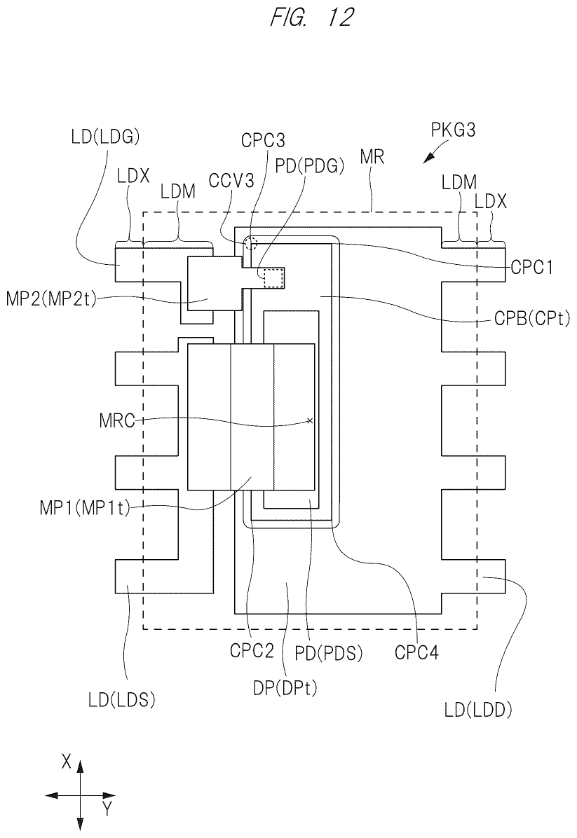

Hereinafter, modification examples of the semiconductor device described referring to FIGS. 1 to 10 will be described. First, a modification example when a planar size of the semiconductor chip is different will be described. FIG. 11 is a perspective plan view illustrating an internal structure of a semiconductor device according to a modification example of FIG. 3. FIG. 12 is a perspective plan view illustrating an internal structure of a semiconductor device according to another modification example of FIG. 3. Each of a semiconductor device PKG2 illustrated in FIG. 11 and a semiconductor device PKG3 illustrated in FIG. 12 is the same as the semiconductor device PKG1 described referring to FIGS. 1 to 9, except for differences described below. Accordingly, duplicate description will not be repeated.

Each of the semiconductor device PKG2 illustrated in FIG. 11 and the semiconductor device PKG3 illustrated in FIG. 12 is different from the semiconductor device PKG1 illustrated in FIG. 3 in terms of the planar size of the semiconductor chip. Each of a semiconductor chip CPA illustrated in FIG. 11 and a semiconductor chip CPB illustrated in FIG. 12 is smaller in planar size (an area in plan view) than the semiconductor chip CP illustrated in FIG. 3. On the other hand, the die pads DP have a planar size similar to the example illustrated in FIG. 3.

In the semiconductor device PKG2 and the semiconductor device PKG3, it is possible to reduce resistance of a conduction path including the metal plate MP1 by shortening the distance between the lead LDS for source and the source electrode pad PDS. Therefore, when an area of the semiconductor chip CPA (or the semiconductor chip CPB illustrated in FIG. 12) is smaller than an area of the die pad DP, the semiconductor chip CPA is mounted at a position closer to the lead LDS for source than the center of the die pad DP. Therefore, a magnitude relationship of the distance from the center MRC of the sealing body MR to each of the plurality of corners of the semiconductor chip may be different from that in the example illustrated in FIG. 3.

That is, in the semiconductor device PKG2 illustrated in FIG. 11, the corner CPC3 among the four corners (corner CPC1, corner CPC2, corner CPC3, and corner CPC4) of the semiconductor chip CPA is located farthest from the center MRC of the sealing body MR. Similarly, in the semiconductor device PKG3 illustrated in FIG. 12, the corner CPC3 among the four corners (corner CPC1, corner CPC2, corner CPC3, and corner CPC4) of the semiconductor chip CPB is located farthest from the center MRC of the sealing body MR. The corner CPC3 is located spaced apart from the metal plate MP1.

In the modification examples illustrated in FIGS. 11 and 12, a crack is likely to occur in the die pad DP in the vicinity of a position overlapping the corner CPC3 among the corner CPC1, the corner CPC2, the corner CPC3, and the corner CPC4. Accordingly, in the modification examples illustrated in FIGS. 11 and 12, a recess portion CCV3 is formed in the die pad DP at the upper surface DPt of the die pad DP at the position overlapping the corner CPC3 where a crack is likely to occur. In other words, the semiconductor chip CPA (or the semiconductor chip CPB) is mounted on the upper surface DPt of the die pad DP such that the corner CPC3 is located at an inside of the recess portion CCV3 in transmissive plan view. A shape and dimension example of the recess portion CCV3 illustrated in FIGS. 11 and 12 is similar to a shape and dimension example of the recess portion CCV1 described referring to FIGS. 8 and 10. Since the recess portion CCV3 is the same as the recess portion CCV1, except that the position of the recess portion CCV3 in the die pad DP at the upper surface DPt of the die pad DP is different from that of the recess portion CCV1 illustrated in FIGS. 8 and 10, duplicate description will not be repeated.

In the modification examples illustrated in FIGS. 11 and 12, it is possible to suppress the occurrence of a crack as long as the semiconductor chip CPA (or the semiconductor chip CPB) is mounted on the die pad DP such that at least the corner CPC3 where a crack is most likely to occur and the recess portion CCV3 overlap with each other in transmissive plan view. Note that, as described below, a recess portion may be formed at a position, that overlaps a corner other than the corner CPC3.

### Modification Examples of Layout of Recess Portion

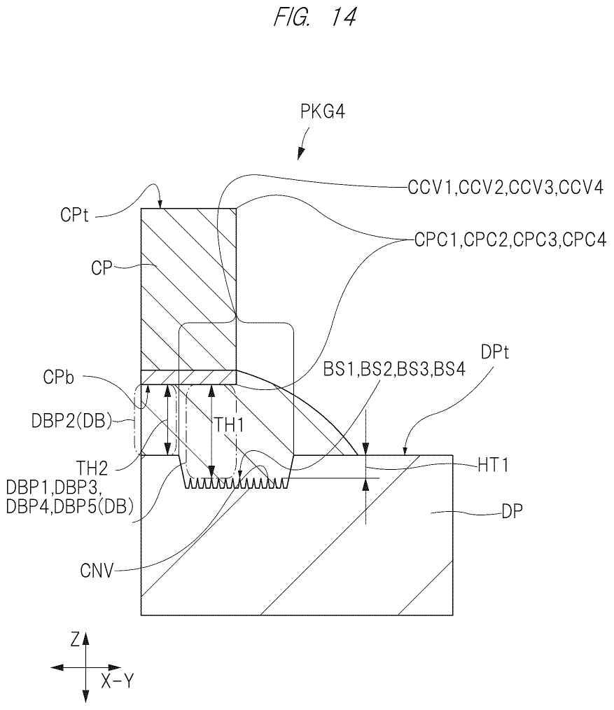

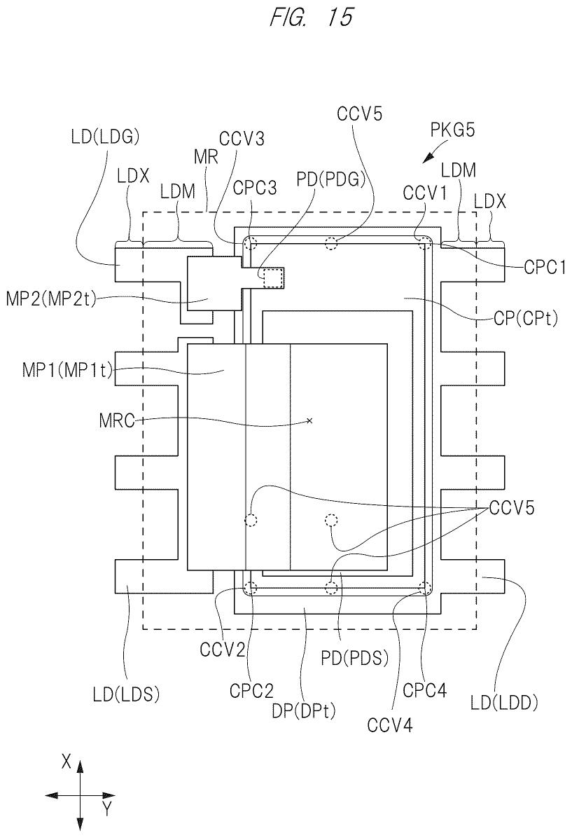

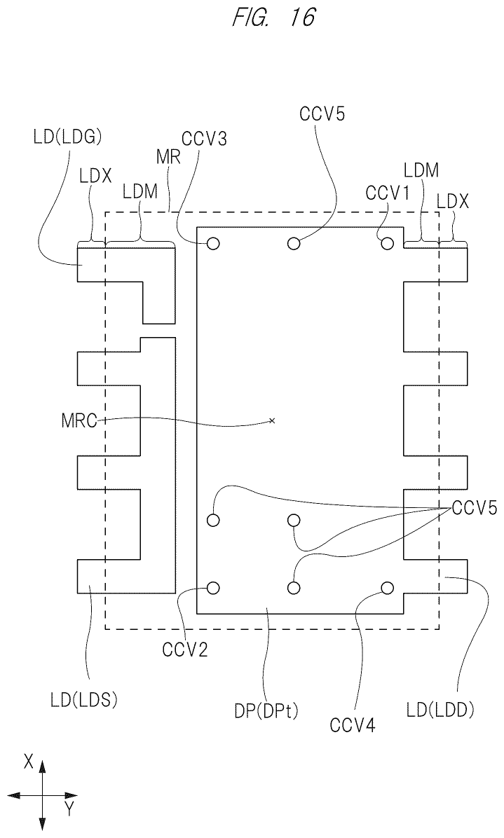

Next, modification examples of the layout of the recess portion illustrated in FIG. 3 will be described. FIG. 13 is a perspective plan view illustrating an internal structure of a semiconductor device according to still another modification example of FIG. 3. FIG. 14 is an enlarged cross-sectional view illustrating a surrounding structure of each of a plurality of corners of a semiconductor chip illustrated in FIG. 13. FIG. 15 is a perspective plan view illustrating an internal structure of a semiconductor device according to a modification example of FIG. 13. FIG. 16 is a plan view of a die pad illustrating a state in which a solder material, a semiconductor chip, and a metal plate illustrated in FIG. 15 are removed. Each of a semiconductor device PKG4 illustrated in FIG. 13 and a semiconductor device PKG5 illustrated in FIG. 15 is the same as the semiconductor device PKG1 described referring to FIGS. 1 to 9, except for differences described below. Accordingly, duplicate description will not be repeated.

Each of the semiconductor device PKG4 illustrated in FIG. 13 and the semiconductor device PKG5 illustrated in FIG. 15 is different from the semiconductor device PKG1 illustrated in FIG. 3 in that a plurality of recess portions is formed in the die pad DP at the upper surface DPt of the die pad DP. As described above, a crack of the solder material DB is likely to occur near a specific corner among the plurality of corners of the semiconductor chip CP. Accordingly, it is possible to suppress the occurrence of a crack by providing the recess portion CCV1 at a position, that overlaps the specific corner in the die pad DP at the upper surface DPt of the die pad DP.

It has been found by a simulation that stress is likely to increase in the vicinity of each of the plurality of corners of the semiconductor chip CP. Accordingly, from a viewpoint of suppressing a crack, as the semiconductor device PKG4 illustrated in FIGS. 13 and 14, it is preferable that the recess portion is provided at each position overlapping the plurality of corners. In other words, it is preferable that the semiconductor chip CP is mounted on the upper surface DPt of the die pad DP such that each of the plurality of corners is located at the inside of the recess portion in transmissive plan view.

As illustrated in FIG. 13, the plurality of corners of the semiconductor chip CP provided in the semiconductor device PKG4 includes the corner CPC1, the corner CPC2, the corner CPC3, and the corner CPC4. In the die pad DP at the upper surface DPt of the die pad DP, a plurality of recess portions including the recess portion CCV1 are formed. The plurality of recess portions includes the recess portion CCV1, a recess portion CCV2, the recess portion CCV3, and a recess portion CCV4.

In transmissive plan view, the semiconductor chip CP is mounted on the die pad DP at the upper surface DPt of the die pad DP such that the corner CPC1 is located at an inside of the recess portion CCV1, the corner CPC2 is located at an inside of the recess portion CCV2, the corner CPC3 is located at an inside of the recess portion CCV3, and the corner CPC4 is located at an inside of the recess portion CCV4.

As illustrated in FIG. 14, the solder material DB has a portion DBP1 that is located between the lower surface CPb of the semiconductor chip CP and the bottom surface BS1 of the recess portion CCV1, a portion DBP3 that is located between the lower surface CPb and a bottom surface BS2 of the recess portion CCV2, a portion DBP4 that is located between the lower surface CPb and a bottom surface BS3 of the recess portion CCV3, a portion DBP5 that is located between the lower surface CPb and a bottom surface BS4 of the recess portion CCV4, and a portion DBP2 that is located between the lower surface CPb and the upper surface DPt of the die pad, the portion DBP2 being at a position different from each of the portion DBP1, the portion DBP3, the portion DBP4, and the portion DBP5.

Each of a thickness TH1 of the solder material DB in the portion DBP1, a thickness TH1 of the solder material DB in the portion DBP3, a thickness TH1 of the solder material DB in the portion DBP4, and a thickness TH1 of the solder material DB in the portion DBP5 is greater than a thickness TH2 of the solder material DB in the portion DBP2.

In the semiconductor device PKG4, since the recess portions are provided at a plurality of positions where stress is likely to increase, the solder material DB has a plurality of thick portions. Accordingly, since it is possible to relax stress at a plurality of positions where stress is likely to increase, it is possible to improve reliability of preventing the occurrence of a crack.

Meanwhile, as described above, from a viewpoint of facilitating alignment, as described referring to FIGS. 3, 11, and 12, it is preferable that the recess portions are disposed only at positions where a crack is particularly likely to occur.

Though not illustrated in the drawings, as an additional modification example of the present modification example, recess portions may be formed selectively at positions overlapping each of two or three corners among the four corners of the semiconductor chip CP illustrated in FIG. 13. According to the examination of the present inventors, a corner having a longer distance from the center MRC of the sealing body MR among the four corners of the semiconductor chip CP is more likely to cause the occurrence of a crack. Accordingly, as a modification example of the example illustrated in FIG. 13, for example, only the recess portion CCV1, the recess portion CCV3, and the recess portion CCV4 may be provided.

In the semiconductor device PKG5 illustrated in FIG. 15, a plurality of recess portions includes a recess portion CCV5 disposed at a position not overlapping any of the plurality of corners of the semiconductor chip CP in transmissive plan view. In the example illustrated in FIG. 15, a plurality of recess portions CCV5 is formed in the die pad DP at the upper surface DPt of the die pad DP. For example, when the semiconductor chip CPA illustrated in FIG. 11 is mounted on the die pad DP, one or both of the corner CPC1 and the corner CPC4 of the semiconductor chip CPA are located at the inside of any of the plurality of recess portions CCV5. In addition, for example, when the semiconductor chip CPB illustrated in FIG. 12 is mounted on the die pad DP, one or all of the corner CPC1, the corner CPC2, and the corner CPC4 of the semiconductor chip CPB are located at the inside of any of the plurality of recess portions CCV5.

Since each of the recess portion CCV2, the recess portion CCV3, the recess portion CCV4, and the recess portion CCV5 illustrated in FIGS. 13, 14, 15, and 16 is the same as the recess portion CCV1, except that the position of each of the recess portions in the die pad DP at the upper surface DPt of the die pad DP is different from the position of the recess portion CCV1 illustrated in FIGS. 8 and 10, duplicate description will not be repeated.

In the semiconductor device PKG5, since a plurality of types of semiconductor chips can be mounted on one type of die pad DP, it is possible to improve versatility of the die pad DP (in other words, versatility of the lead frame).

### Modification Example of Shape of Recess Portion

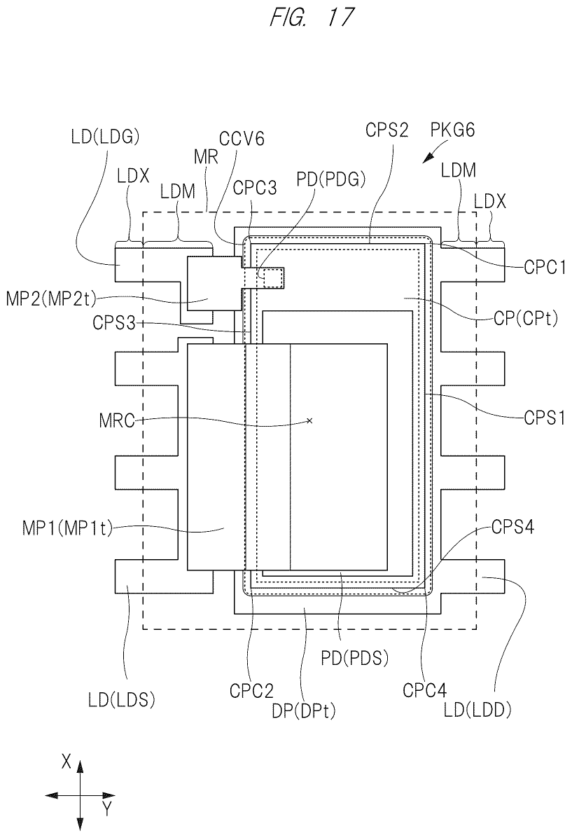

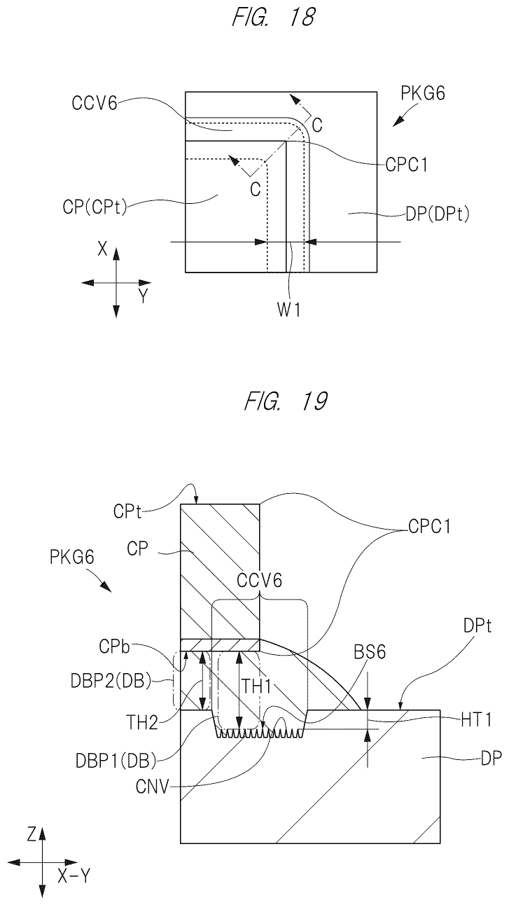

Next, a modification example of the shape of the recess portion illustrated in FIG. 3 will be described. FIG. 17 is a perspective plan view illustrating an internal structure of a semiconductor device according to another modification example of FIG. 13. FIG. 18 is an enlarged plan view of a portion of a recess portion having a groove shape illustrated in FIG. 17 on an enlarged scale. FIG. 19 is an enlarged cross-sectional view taken along line C-C of FIG. 18. A semiconductor device PKG6 illustrated in FIGS. 17 to 19 is the same as the semiconductor device PKG4 illustrated in FIG. 13, except for a difference described below. Accordingly, duplicate description will not be repeated.

The semiconductor device PKG6 is different from the semiconductor device PKG4 illustrated in FIG. 13 in that a shape of a recess portion CCV6 formed in the die pad DP at the upper surface DPt of the die pad DP extends in a groove shape.

The semiconductor chip CP can be described as follows. That is, the semiconductor chip CP includes four sides in plan view. In the example illustrated in FIG. 17, the semiconductor chip CP includes a side CPS1 that extends in the X direction, a side CPS2 that extends in the Y direction, a side CPS3 that extends in the X direction and is positioned on an opposite side to the side CPS1, and a side CPS4 that extends in the Y direction and is positioned on an opposite side to the side CPS2.

Four corners of the semiconductor chip CP are intersection points of any two sides among the four sides. In the example illustrated in FIG. 17, the corner CPC1 is an intersection point of the side CPS1 and the side CPS2. The corner CPC2 is an intersection point of the side CPS3 and the side CPS4. The corner CPC3 is an intersection point of the side CPS2 and the side CPS3. The corner CPC4 is an intersection point of the side CPS1 and the side CPS4.

The recess portion CCV6 formed in the die pad DP at the upper surface DPt of the die pad DP of the semiconductor device PKG6 extends to have a quadrangular frame shape in plan view. In addition, in transmissive plan view, the semiconductor chip CP is mounted on the upper surface DPt of the die pad DP such that each of the plurality of corners and the four sides overlaps the recess portion CCV6.

As already described, a crack of the solder material DB is likely to occur near a specific corner among the plurality of corners of the semiconductor chip CP. Accordingly, it is possible to suppress the occurrence of a crack by providing the recess portion CCV1 at a position, that overlaps the specific corner in the die pad DP at the upper surface DPt of the die pad DP.

However, it has been found by a simulation that stress is likely to increase near an outer edge of the semiconductor chip CP (an outer edge of the semiconductor chip CP in plan view) next to near the plurality of corners. Accordingly, from a viewpoint of suppressing the occurrence of a crack, as the semiconductor device PKG6 illustrated in FIGS. 17 to 19, it is preferable that the recess portion CCV6 is provided at the position overlapping each of the plurality of corners and the plurality of sides.

The groove-shaped recess portion CCV6 illustrated in FIGS. 17 to 19 is formed by laser irradiation similarly to the recess portion CCV1 illustrated in FIGS. 8 and 10 already described. Note that, since an opening shape of the recess portion CCV6 is a rectangular shape and not a circular shape, for example, laser irradiation is performed along an extension direction of the groove of the recess portion CCV6.

In the present embodiment, the recess portion CCV6 is formed by irradiation of laser having a spot diameter smaller than an opening width W1 (see FIG. 18) of the recess portion CCV6. The opening width W1 is, for example, about 400 μm. The opening width W1 is defined as an opening length in a direction perpendicular to the extension direction of the recess portion CCV6.

As described above, when the recess portion CCV6 is formed by irradiation of laser having a spot diameter smaller than the opening width W1 of the recess portion CCV6, the recess portion CCV6 having a shape as illustrated in FIG. 19 is obtained. That is, as illustrated in FIG. 19, groove-shaped unevenness are formed in a bottom surface BS6 of the recess portion CCV6.

Though not illustrated in the drawings, there are various modification examples to an extension direction of a plurality of protrusion portions CNV illustrated in FIG. 19. For example, in the example illustrated in FIG. 19, a plurality of unevenness extends along the extension direction of the recess portion CCV6 having the frame shape. Note that, as a modification example, the protrusion portions CNV may extend in a width direction of the groove-shaped recess portion CCV6 (a direction illustrated as the opening width W1).

In the example illustrated in FIG. 17, the recess portion CCV6 overlaps all corners and all sides of the semiconductor chip CP. As a modification example, a shape of a portion of the shape of the recess portion CCV6 illustrated in FIG. 17 may be replaced with the shape of the recess portion CCV1 illustrated in FIG. 3 or the shape of the recess portion CCV2, the recess portion CCV3, and the recess portion CCV4 illustrated in FIG. 13.

### Modification Example of Solder Material

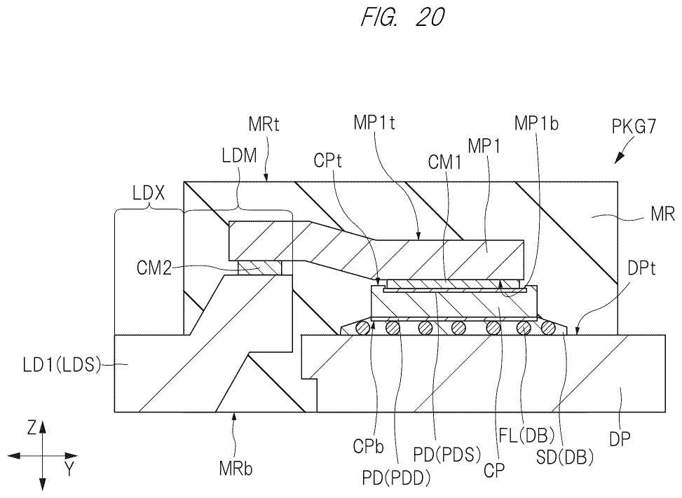

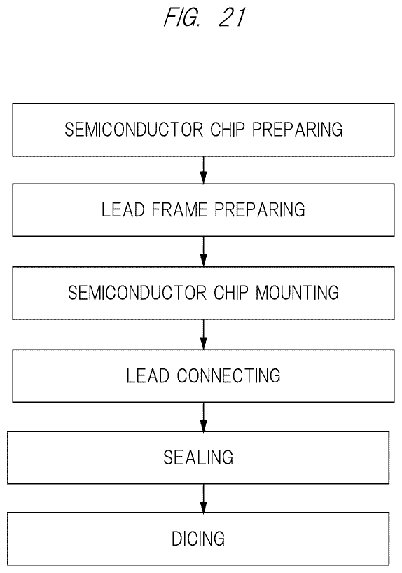

Next, a modification example of the solder material illustrated in FIG. 4 will be described. FIG. 20 is a cross-sectional view of a semiconductor device according to a modification example of FIG. 4. A semiconductor device PKG7 illustrated in FIG. 20 is the same as the semiconductor device PKG1 described referring to FIGS. 1 to 9, except for a difference described below. Accordingly, duplicate description will not be repeated.

The semiconductor device PKG7 is different from the semiconductor device PKG1 illustrated in FIG. 4 in terms of a material for the solder material DB. That is, the solder material DB in the semiconductor device PKG7 contains solder SD and a plurality of fillers (inorganic material particles) FL mixed in the solder SD, and silica particles can be provided as an example of the fillers FL.

In each of a plurality of embodiments already described, the recess portion is provided at a position, that overlaps the outer edge of the semiconductor chip CP in transmissive plan view. When the semiconductor chip CP is mounted such that the lower surface CPb of the semiconductor chip CP and the upper surface DPt of the die pad DP are parallel to each other, it is possible to make the thickness TH1 of the solder material DB in the portion DBP1 illustrated in FIG. 8 close to a design value by improving processing accuracy of the recess portion.

Note that, when the semiconductor chip CP is mounted to be inclined with respect to the upper surface DPt of the die pad DP as the recess portion is formed, a value of the thickness TH1 of the solder material DB in the portion DBP1 may be deviated from an allowable range.

Accordingly, in the present modification example, the plurality of fillers FL is mixed in the solder material DB such that the lower surface CPb of the semiconductor chip CP and the upper surface DPt of the die pad DP are regarded to be substantially parallel to each other.

A particle size of the plurality of fillers FL is, for example, about 20 μm to 40 μm. The value is determined based on a design value of a separation distance between the lower surface CPb and the upper surface DPt after the semiconductor chip CP is mounted on the die pad DP. When the solder material DB contains the plurality of fillers FL, the fillers FL function as a spacer member. As a result, it is possible to suppress the inclination of the semiconductor chip CP with respect to the upper surface DPt of the die pad DP.

### Method of Manufacturing Semiconductor Device

Next, a method of manufacturing the semiconductor device described referring to FIGS. 1 to 10 will be described. FIG. 21 is an explanatory view illustrating an example of a manufacturing process of the semiconductor device described referring to FIGS. 1 to 10. Hereinafter, as a representative example of the method of manufacturing a semiconductor device, a method of manufacturing the semiconductor device PKG1 described referring to FIGS. 1 to 10 will be mainly described. In regard to a method of manufacturing the semiconductor device PKG2 illustrated in FIG. 11, a method of manufacturing the semiconductor device PKG3 illustrated in FIG. 12, a method of manufacturing the semiconductor device PKG4 illustrated in FIG. 13, a method of manufacturing the semiconductor device PKG5 illustrated in FIG. 15, a method of manufacturing the semiconductor device PKG6 illustrated in FIG. 17, and a method of manufacturing a semiconductor device PKG7 illustrated in FIG. 20, duplicate description will not be repeated, and differences will be described.

The method of manufacturing the semiconductor device illustrated in FIG. 21 includes a semiconductor chip preparation step, a lead frame preparation step, a semiconductor chip mounting step, a lead connection step, a sealing step, and a dicing step.

In the semiconductor chip preparation step illustrated in FIG. 21, for example, the semiconductor chip CP illustrated in FIGS. 3 and 4 (may be the semiconductor chip CPA illustrated in FIG. 11 or the semiconductor chip CPB illustrated in FIG. 12) is prepared. Since the shape and structure of the semiconductor chip CP are already described in detail, duplicate description will not be repeated.

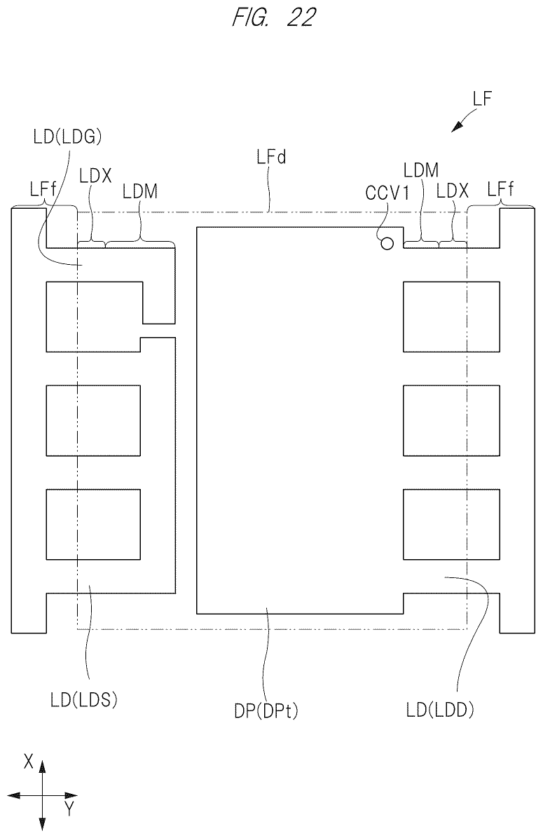

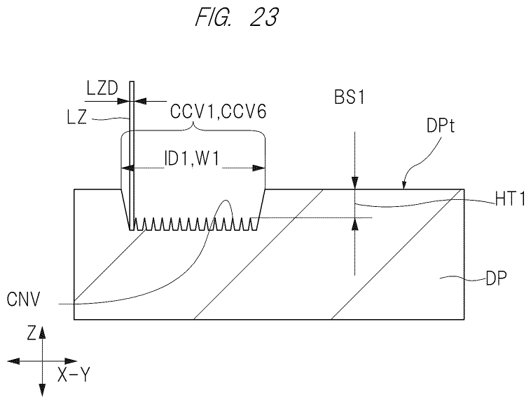

In the lead frame preparation step illustrated in FIG. 21, a lead frame illustrated in FIG. 22 is prepared. FIG. 22 is an enlarged plan view of a lead frame that is prepared in the lead frame preparation step illustrated in FIG. 21. FIG. 23 is an enlarged cross-sectional view illustrating an example of a state in which an upper surface of a die pad is irradiated with laser to form a recess portion in the lead frame preparation step illustrated in FIG. 21.

A lead frame LF that is prepared in the present step includes a device forming portion LFd that is connected with a frame portion LFf. In FIG. 22, one of a plurality of device forming portions LFd in the lead frame LF is illustrated. The plurality of device forming portions LFd is connected with each other via the frame portion LFf.

The lead frame LF is made of, for example, copper (Cu) or a copper alloy. Each of the plurality of device forming portions LFd is connected with the frame portion LFf. The frame portion LFf is a support portion that supports each member formed in the device forming portion LFd until the dicing step illustrated in FIG. 21.

The device forming portion LFd corresponds to one semiconductor device PKG1 illustrated in FIG. 1. The device forming portion LFd includes the die pad DP and the plurality of leads LD. Among the plurality of leads LD, each of the lead LDS for source and the lead LDG for gate is spaced apart from the die pad DP. On the other hand, the lead LDD for drain is formed integrally with the die pad DP. In the example illustrated in FIG. 22, the die pad DP is supported by the frame portion LFf via the lead LDD for drain. Note that, as a modification example, a suspension lead (support lead) (not illustrated) may be connected with the die pad DP.

The recess portion CCV1 already described is formed in advance in the die pad DP at the upper surface DPt of the die pad DP. For example, as illustrated in FIG. 23, the recess portion CCV1 is formed by irradiating the upper surface DPt of the die pad DP with laser LZ. As described above, as a modification example, the recess portion CCV1 can be formed by press working using a mold. In a case of a method of forming the recess portion CCV1 by laser irradiation, it is preferable in that unevenness or distortion is less likely to occur in the upper surface DPt in the vicinity of the recess portion CCV1 compared to the method of forming the recess portion CCV1 by press working.

In the example illustrated in FIG. 23, a spot diameter LZD of the laser LZ is smaller than, for example, the opening diameter ID1 of the recess portion CCV1. In a case of forming the recess portion CCV6 formed in the die pad DP of the semiconductor device PKG6 described referring to FIGS. 17 to 19, the spot diameter LZD of the laser LZ is smaller than, for example, the opening width W1 of the recess portion CCV6. Here, it is preferable in that it is possible to control the opening area or depth of the recess portion CCV1 with high accuracy compared to a case of increasing the spot diameter LZD of the laser LZ to form the recess portion CCV6 with single irradiation.

Since a method of forming each of the recess portion CCV2, the recess portion CCV3, the recess portion CCV4, and the recess portion CCV5 described in each of FIGS. 11, 12, 13, 15, and 16 is similar to a method of forming the recess portion CCV1 illustrated in FIG. 23, duplicate description will not be repeated.

Next, in the semiconductor chip mounting step illustrated in FIG. 21, as illustrated in FIG. 4, the semiconductor chip CP is mounted on the die pad DP via the solder material DB such that the lower surface CPb of the semiconductor chip CP and the upper surface DPt of the die pad DP face to each other.

Specifically, first, solder paste that is a raw material of the solder material DB is applied onto a chip mounting region that is a region in the upper surface DPt of the die pad DP where the semiconductor chip CP is to be mounted (solder material application step). The solder paste is a paste-form material containing a solder component and a flux component. In the method of manufacturing the semiconductor device PKG7 described referring to FIG. 20, the solder paste contains the solder SD and the plurality of fillers FL (inorganic material particles) mixed in the solder SD.

Next, after the solder material DB spreads as necessary, the semiconductor chip CP is disposed on the solder material DB and is pressed toward the die pad DP. In the step of disposing the semiconductor chip CP on the solder material DB, alignment is performed such that the corner CPC1 of the semiconductor chip CP is positioned on the recess portion CCV1 of the die pad DP. By the present step, the semiconductor chip CP is adhered on the die pad via the paste-form solder material DB (solder paste). Here, as illustrated in FIG. 8, the semiconductor chip CP is mounted on the die pad DP at the upper surface DPt of the die pad DP such that the corner CPC1 is located at the inside of the recess portion CCV1. The solder material DB is adhered to the entire lower surface CPb of the semiconductor chip CP.

Next, the solder paste is heated as reflow processing to increase the temperature to a melting point of the solder component contained in the solder paste or higher and is then cooled. By the reflow processing, the solder material DB is cured, and the semiconductor chip CP is fixed on the solder material DB. In the reflow processing, the flux component contained in the solder paste is volatilized. When the flux component remains as a residue, a cleaning step may be performed to remove the residue of the flux component. As described as a modification example referring to FIG. 20, when the solder material DB contains the solder SD and the fillers FL, the fillers FL remain in the solder material DB even after the reflow processing is performed.

When solder is used as the conductive member CM1 and the conductive member CM2 illustrated in FIG. 4, the reflow processing may be performed together in the lead connection step illustrated in FIG. 21.

Next, in the lead connection step illustrated in FIG. 21, as illustrated in FIG. 4, a plurality of leads and the semiconductor chip are electrically connected via the metal plate MP1. In the present step, the conductive member CM1 is disposed on the source electrode pad PDS of the semiconductor chip CP. In addition, in the present step, the conductive member CM2 is applied onto the upper surface of the inner lead portion LDM of the lead LD. Each of the conductive member CM1 and the conductive member CM2 used in the present step is, for example, solder paste or conductive resin paste. Here, a conductive member (not illustrated) is applied onto the gate electrode pad PDG illustrated in FIG. 3.

Next, the metal plate MP1 is disposed to cover the conductive member CM1 and the conductive member CM2 illustrated in FIG. 4 and the lower surface MP1b of the metal plate MP1 is bonded to each of the conductive member CM1 and the conductive member CM2. Here, the metal plate MP2 is disposed on the gate electrode pad PDG illustrated in FIG. 3 and is bonded to the conductive member (not illustrated).

Next, each of the conductive member CM1 and the conductive member CM2 is cured to fix the metal plate MP1. As a method of curing each of the conductive member CM1 and the conductive member CM2, for example, there is the following method. When solder paste is used as the conductive member CM1 and the conductive member CM2, the reflow processing is performed to cure the solder paste. On the other hand, when conductive resin paste is used as the conductive member CM1 and the conductive member CM2, as curing/baking processing, the conductive resin paste is heated to a temperature at which thermosetting resin contained in the conductive resin paste is cured. Accordingly, the resin component of the conductive resin paste is cured. As a result, it is possible to cure each of the conductive member CM1 and the conductive member CM2 made of conductive resin paste.

The above description is the description of the manufacturing process when a so-called clip is used as the metal plate MP1 and the metal plate MP2 (see FIG. 3). When a band-shaped metal plate called a ribbon is used instead of the clip, it is possible to bond the metal plate by a method similar to wire bonding. Here, one end portion of the metal plate MP1 is bonded directly to the source electrode pad PDS without interposing the conductive member CM1 and the conductive member CM2. On the other hand, the other end portion of the metal plate MP1 is bonded to (plated a metal thin-film film (not illustrated)) formed on the upper surface of the inner lead portion LDM of the lead.

Next, in the sealing step illustrated in FIG. 21, as illustrated in FIG. 4, the semiconductor chip CP and the metal plate MP1 are sealed with insulating resin. In the present step, in addition to the semiconductor chip CP and the metal plate MP1, the inner lead portions LDM of the plurality of leads LD illustrated in FIG. 3, the metal plate MP2, and the upper surface DPt and the side surface of the die pad DP are sealed with the sealing body made of an insulating material. The sealing body MR may contain insulating particles made of an inorganic material, a pigment, or the like in addition to resin.

The center MRC of the sealing body MR illustrated in FIG. 3 does not necessarily match the center of the die pad DP. According to the examination of the present inventors, it has been found that, among the plurality of corners of the semiconductor chip CP, a corner closest to a place where a crack of the solder material DB occurs can be determined according to the length of the distance from the center MRC of the sealing body MR. That is, the corner CPC1 illustrated in FIG. 3 is at a position having a longest distance from the center MRC of the sealing body MR among the four corners of the semiconductor chip CP.

Meanwhile, the corner CPC2 illustrated in FIG. 3 is at a position having a shortest distance from the center MRC of the sealing body MR among the four corners of the semiconductor chip CP. Therefore, as described referring to FIG. 9, the recess portion CCV1 illustrated in FIG. 8 is not disposed at a position, that overlaps the corner CPC2. In other words, the corner CPC2 is located at the outside of the recess portion CCV1 illustrated in FIG. 8 in transmissive plan view.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a semiconductor chip including a first upper surface and a first lower surface positioned on an opposite side to the first upper surface;
a die pad including a second upper surface facing the first lower surface and a second lower surface positioned on an opposite side to the second upper surface, the semiconductor chip being mounted on the second upper surface;
a plurality of leads electrically connected with the semiconductor chip;
a metal plate electrically connected with each of the plurality of leads and the semiconductor chip; and
a sealing body with which the semiconductor chip is sealed,
wherein the semiconductor chip is mounted on the second upper surface of the die pad via a solder material,
wherein, in plan view, the semiconductor chip includes a plurality of corners including a first corner,
wherein a recess portion is formed in the die pad at the second upper surface of the die pad,
wherein the semiconductor chip is mounted on the second upper surface of the die pad such that the first corner is located at an inside of the recess portion in transmissive plan view,
wherein, in transmissive plan view, the first corner is located farthest from a center of the sealing body and is spaced apart from the metal plate, among the plurality of corners,
wherein the solder material has:
a first portion that is located between the first lower surface of the semiconductor chip and a bottom surface of the recess portion; and
a second portion that is located between the first lower surface of the semiconductor chip and the second upper surface of the die pad and that is located at a position which is different from the first portion, and
wherein a thickness of the solder material in the first portion is greater than a thickness of the solder material in the second portion.

2. The semiconductor device according to claim 1,
wherein a groove-shaped unevenness is formed in the recess portion at the bottom surface of the recess portion.

3. The semiconductor device according to claim 2,
wherein, in plan view, an outer edge of the recess portion has a circular shape and the groove-shaped unevenness has a spiral shape.

4. The semiconductor device according to claim 2,
wherein a height difference between a protrusion portion of the bottom surface of the recess portion and the second upper surface of the die pad is 30 μm or more.

5. The semiconductor device according to claim 1,
wherein, in plan view, the plurality of corners of the semiconductor chip includes the first corner and a second corner,
wherein, in transmissive plan view, the second corner is located closer to the center of the sealing body than the first corner,
wherein the second corner of the semiconductor chip is located at an outside of the recess portion in transmissive plan view, and
wherein, a shortest distance from the first lower surface of the semiconductor chip at the second corner to the second upper surface of the die pad is smaller than a thickness of the solder material in the first portion.

6. The semiconductor device according to claim 1,
wherein, in transmissive plan view, the first corner is located farthest from the center of the sealing body and is most spaced apart from the metal plane, among the plurality of corners.

7. The semiconductor device according to claim 1,
wherein the plurality of corners of the semiconductor chip includes the first corner, a second corner, a third corner, and a fourth corner,
wherein, in the die pad at the second upper surface of the die pad, a second recess portion, a third recess portion, and a fourth recess portion are formed in addition to the recess portion,
wherein, in transmissive plan view, the semiconductor chip is mounted on the second upper surface of the die pad such that the first corner is located at the inside of the recess portion, the second corner is located at an inside of the second recess portion, the third corner is located at an inside of the third recess portion, and the fourth corner is located at an inside of the fourth recess portion,
wherein the solder material has: the first portion that is located between the first lower surface of the semiconductor chip and the bottom surface of the recess portion; a third portion that is located between the first lower surface and a bottom surface of the second recess portion; a fourth portion that is located between the first lower surface and a bottom surface of the third recess portion; a fifth portion that is located between the first lower surface and a bottom surface of the fourth recess portion; and the second portion that is located between the first lower surface and the second upper surface of the die pad and that is located at the position which is different from each of the first portion, the third portion, the fourth portion, and the fifth portion, and
wherein each of the thickness of the solder material in the first portion, a thickness of the solder material in the third portion, a thickness of the solder material in the fourth portion, and a thickness of the solder material in the fifth portion is greater than the thickness of the solder material in the second portion.

8. The semiconductor device according to claim 7,
wherein, in addition to the recess portion, the second recess portion, the third recess portion, and the fourth recess portion, a fifth recess portion located at a position not overlapping any of the plurality of corners of the semiconductor chip in transmissive plan view is formed in the die pad at the second upper surface of the die pad.

9. The semiconductor device according to claim 1,
wherein the semiconductor chip has four sides and the plurality of corners that is an intersection point of any two sides of the four sides,
wherein, in plan view, the recess portion extends in a groove shape to have a quadrangular frame shape,
wherein, in transmissive plan view, the semiconductor chip is mounted on the second upper surface of the die pad such that each of the plurality of corners and the four sides is located at the inside of the recess portion.

10. The semiconductor device according to claim 1,
wherein the solder material contains solder and a plurality of inorganic material particles mixed in the solder.

11. The semiconductor device according to claim 1,
wherein the semiconductor chip includes a first electrode pad disposed on the first upper surface, and
wherein the metal plate is electrically connected with the first electrode pad via a conductive member disposed between the metal plate and the first electrode pad and connected with each of the metal plate and the first electrode pad.

12. The semiconductor device according to claim 11,
wherein the semiconductor chip has a power transistor configured by a power MOSFET or an IGBT,
wherein the first electrode pad is electrically connected with a source of the power MOSFET or an emitter of the IGBT, and
wherein the die pad is electrically connected with a drain of the power MOSFET or a collector of the IGBT via the solder material.

13. A method of manufacturing a semiconductor device, the method comprising steps of:
(a) preparing a semiconductor chip including a first upper surface and a first lower surface positioned on an opposite side to the first upper surface;
(b) preparing a lead frame having a die pad including a second upper surface and a second lower surface positioned on an opposite side to the second upper surface, and a plurality of leads spaced apart from the die pad;
(c) mounting the semiconductor chip on the die pad via a solder material such that the first lower surface of the semiconductor chip and the second upper surface of the die pad face to each other;
(d) electrically connecting the plurality of leads and the semiconductor chip with each other via a metal plate; and
(e) forming a sealing body with which the semiconductor chip and the metal plate are sealed,
wherein the semiconductor chip prepared in the step of (a) includes a plurality of corners including a first corner in plan view,
wherein a recess portion is formed in the die pad at the second upper surface of the die pad of the lead frame prepared in the step of (b),
wherein, in the step of (c),
the semiconductor chip is mounted on the second upper surface of the die pad such that the first corner is located at an inside of the recess portion in transmissive plan view; and
the solder material is adhered to entire of the first lower surface of the semiconductor chip,
wherein, after the step of (c),
the solder material has: a first portion that is located between the first lower surface of the semiconductor chip and a bottom surface of the recess portion; and a second portion that is located between the first lower surface of the semiconductor chip and the second upper surface of the die pad and that is located at a position which is different from the first portion; and
a thickness of the solder material in the first portion is greater than a thickness of the solder material in the second portion, and
wherein, after the step of (e), the first corner of the semiconductor chip is located farthest from a center of the sealing body and is spaced apart from the metal plate, among the plurality of corners.

14. The method according to claim 13,
wherein the recess portion is formed by irradiating the second upper surface of the die pad with laser.

15. The method according to claim 14,
wherein an opening diameter or an opening width of the recess portion is greater than a spot diameter of the laser, and
wherein a groove-shaped unevenness is formed in the recess portion at the bottom surface of the recess portion.

16. The method according to claim 13,
wherein, in plan view, the plurality of corners of the semiconductor chip includes the first corner and a second corner,
wherein, after the step of (e), the second corner is located closer to the center of the sealing body than the first corner, and
wherein, after the step of (c),
the second corner of the semiconductor chip is located at an outside of the recess portion in transmissive plan view, and
a shortest distance from the first lower surface of the semiconductor chip at the second corner to the second upper surface of the die pad is smaller than a thickness of the solder material in the first portion.

17. The method according to claim 13,
wherein, after the step of (e), the first corner of the semiconductor chip is located farthest from the center of the sealing body and is most spaced apart from the metal plate, among the plurality of corners.

18. The method according to claim 13,
wherein, in the step of (c), the solder material contains solder and a plurality of inorganic material particles mixed in the solder.
